(19) United States
(12) Patent Application Publication
(10) Pub. No.: US 2020/0243698 A1
(43) Pub. Date: Jul. 30, 2020

(54) PHOTOELECTRIC DETECTOR AND METHOD FOR PHOTOELECTRIC CONVERSION

(71) Applicants: Tsinghua University, Beijing (CN); HON HAI PRECISION INDUSTRY CO., LTD., New Taipei (TW)

(72) Inventors: ZHONG-ZHENG HUANG, Beijing (CN); TIAN-FU ZHANG, Beijing (CN); XIAO-YANG XIAO, Beijing (CN); JIE ZHAO, Beijing (CN); QUN-QING LI, Beijing (CN); SHOU-SHAN FAN, Beijing (CN)

(21) Appl. No.: 16/713,329

(22) Filed: Dec. 13, 2019

(30) Foreign Application Priority Data
Jan. 25, 2019 (CN) 201910073718.6

(51) Int. Cl. H01L 31/032; H01L 31/20; H01L 31/02; H01L 31/09; H01L 31/0376; H01L 31/0392

(52) U.S. Cl. CPC H01L 31/032; H01L 31/20; H01L 31/0392; H01L 31/095; H01L 31/0376; H01L 31/02016

(57) ABSTRACT

A photoelectric detector, which includes a substrate, a MoS₂ semiconductor layer, an electrical signal detector, a first electrode and a second electrode. Said MoS₂ semiconductor layer is located on the substrate, with the first electrode and the second electrode spaced from each other and electrically connected to the MoS₂ semiconductor layer respectively. The electrical signal detector is configured to detect changes in electrical properties of the MoS₂ semiconductor layer, and the material of the MoS₂ semiconductor layer is amorphous MoS₂ sheet.

### CROSS-REFERENCE TO RELATED APPLICATIONS

This application claims all benefits under 35 U.S.C. § 119 from the Chinese Patent Application No. 201910073718.6, filed on Jan. 25, 2019, in the China Intellectual Property Office, the disclosure of which is incorporated herein by reference.

### FIELD

The subject matter herein generally relates to a photoelectric detector and a method for photoelectric conversion.

### BACKGROUND

Photoelectric detectors can detect light by converting light into electric signal. The photoelectric detectors have wide range of applications including imaging, sensing, or communications, etc. The semiconductor is one of the most important components in the photoelectric detector because the detectable spectrum range depends on the energy band gap of the semiconductors. Up to now, the detections of photon of ultraviolet, visible, near-infrared, mid-infrared regimes have been achieved by utilizing different band gaps of the semiconductors, such as GaN, Si, InGaAs and HdCdTe respectively. With the soaring demand in applications such as imaging, communication and broadband detection, photoelectric detectors with broadband response at room temperature have become an urgent demand.

Molybdenum disulfide (MoS₂) is a promising 2D material with strong photon-electron interaction and high absorption in the spectra range within the band gap ranging from 1.2 to 1.8 eV. Recently, a broadband polycrystalline MoS₂ photoelectric detector was reported to realize spectral response from 445 to 2717 nm with a maximum photo responsivity of about 32 mA W⁻¹ at 1550 nm. However, the polycrystalline MoS₂ is prepared by the pulsed laser deposition technique, which need a high substrate temperature up to 600 Celsius degrees or even higher. And such a manufacturing method has a high cost.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views. Implementations of the present technology will be described, by way of example only, with reference to the attached figures.

FIG. 1 is a schematic view of one embodiment of a photoelectric detector.

FIG. 2 is an X-ray diffraction (XRD) pattern of an amorphous MoS₂ sheet before and after annealing.

FIG. 3a and FIG. 3b are Transmission Electron Microscopy (TEM) images of the amorphous MoS₂ sheet before and after annealing, respectively.

FIG. 4 is a flow chart of one embodiment of a method for making a MoS₂ semiconductor layer.

FIG. 5a is an X-ray photoelectron spectroscopy (XPS) spectrum of the MoS₂ semiconductor layer.

FIG. 5b is an XPS spectrum of the Mo 3d.

FIG. 5c is an XPS spectrum of the S 2p.

FIG. 6a is a graph of the photocurrent and the bias voltage at different RF power.

FIG. 6b is a graph of a relationship between the responsivity of the photoelectric detector and the RF power.

FIG. 7a is a graph of the photocurrent and the bias voltage at different pressure.

FIG. 7b is a graph of a relationship between the responsivity of the photoelectric detector and the pressure.

FIG. 8a is a graph of the photocurrent and the bias voltage at different thickness of the amorphous MoS₂ sheet.

FIG. 8b is a graph of a relationship between the responsivity R_{λ}, the detection rate D* of the photoelectric detector and the thickness of the amorphous MoS₂ sheet.

FIG. 9a is a graph of the photocurrent and the bias voltage with different electrode materials.

FIG. 9b is a graph of a relationship between the responsivity of the photoelectric detector and the electrode materials.

FIG. 10 is a flow chart of one embodiment of a method for photoelectric conversion.

FIG. 11a is a graph of an absorbance of the photoelectric detector at different light wavelengths.

FIG. 11b is a partial enlarged view of FIG. 11a.

FIG. 12a is a graph of the photocurrent and the bias voltage at different wavelengths of the incident light.

FIG. 12b is a graph of a relationship between the responsivity R_{λ}, the detection rate D* of the photoelectric detector and wavelengths of the incident light.

FIG. 13a is a time dependence of photocurrent measured under the illumination with a wavelength of 973 nm and at a bias voltage V_{ds}=1V.

FIG. 13b is a part of rise time of the FIG. 13a.

FIG. 13c is a part of decay time of the FIG. 13a.

### DETAILED DESCRIPTION

It will be appreciated that for simplicity and clarity of illustration, where appropriate, reference numerals have been repeated among the different figures to indicate corresponding or analogous elements. In addition, numerous specific details are set forth to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale, and the proportions of certain parts may be exaggerated to better illustrate details and features. The description is not to be considered as limiting the scope of the embodiments described herein.

Several definitions that apply throughout this disclosure will now be presented.

The connection can be such that the objects are permanently connected or releasably connected. The term “substantially” is defined to be essentially conforming to the particular dimension, shape, or other feature that the term modifies, such that the component need not be exact. The term “comprising” means “including, but not necessarily limited to”; it specifically indicates open-ended inclusion or membership in a so-described combination, group, series, and the like. It should be noted that references to “an” or “one” embodiment in this disclosure are not necessarily to the same embodiment, and such references mean “at least one”.

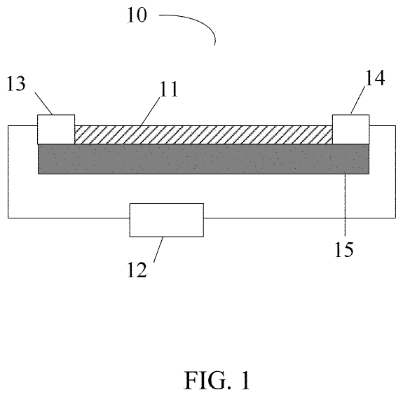

In FIG. 1, a photoelectric detector 10 of one embodiment is provided. The photoelectric detector 10 includes a MoS₂ semiconductor layer 11, an electrical signal detector 12, a first electrode 13, a second electrode 14 and a substrate 15. The MoS₂ semiconductor layer 11 is located on the substrate 15. The MoS₂ semiconductor layer 11 is electrically connected to the first electrode 13 and the second electrode 14 respectively. The first electrode 13 and the second electrode 14 are spaced apart from each other. The electrical signal detector 12 is electrically connected to the MoS₂ semiconductor layer 11 through the first electrode 13 and the second electrode 14. The electrical signal detector 12 is configured to detect changes of electrical properties of the MoS₂ semiconductor layer 11. The MoS₂ semiconductor layer 11, the first electrode 13, the electrical signal detector 12 and the second electrode 14 are sequentially electrically connected to form a circuit loop.

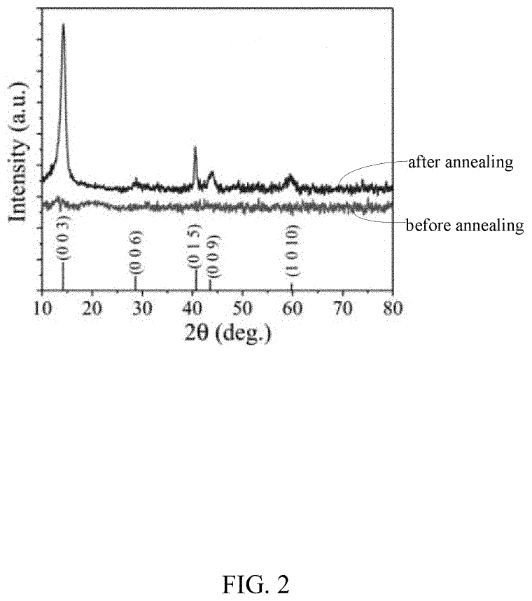

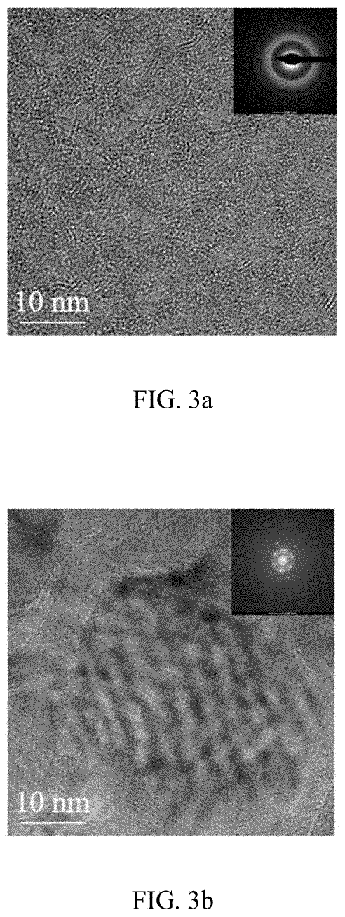

The MoS₂ semiconductor layer 11 includes at least one amorphous MoS₂ sheet. The amorphous MoS₂ sheet is a two-dimensional semiconductor material. The amorphous MoS₂ sheet can convert photons into electron-hole after absorbing photons. The amorphous MoS₂ sheet has a bandgap E_{g} of at least 0.196 eV. Since the wavelength λ of absorbed light can satisfy λ=1243/E_{g}, light having a wavelength of 6340 nm can be absorbed by the amorphous MoS₂ sheet. Referring to FIG. 2, the XRD pattern of the amorphous MoS₂ sheet before and after annealing are showed. The XRD pattern without typical peaks represents the amorphous phase, and the XRD pattern with typical peaks represents the crystal phase. There is no typical peak of MoS₂ until the amorphous MoS₂ sheet is annealed. Referring to FIG. 3a and FIG. 3b show the TEM characterization of the amorphous MoS₂ sheet before and after annealing, respectively. The amorphous MoS₂ sheet is converted into the crystal phase during annealing. The thickness of the MoS₂ semiconductor layer 11 is in a range of 10 nanometers to 150 nanometers. In one embodiment, the thickness of the MoS₂ semiconductor layer 11 is 114.5 nanometers.

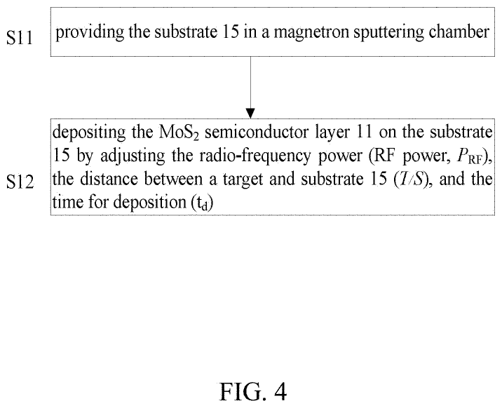

Referring to FIG. 4, the MoS₂ semiconductor layer 11 can be obtained by magnetron sputtering. The method of making the MoS₂ semiconductor layer 11 by magnetron sputtering comprises the following steps:

step (S11), providing the substrate 15 in a magnetron sputtering device;

step (S12), depositing the MoS₂ semiconductor layer 11 on the substrate 15 by adjusting the radio-frequency power (RF power, P_{RF}), the distance between a target and the substrate 15 (T/S), and the time for deposition (t_{d}).

In step S11, the vacuum degree of the magnetron sputtering device before argon gas is introduced is kept as 3×10⁻⁵ Pa. The pressure of the magnetron sputtering device is defined as P after introducing argon gas. The temperature of the substrate 15 is defined as Tₛ, the temperature Tₛ is in a range of 20 Celsius degrees to 28. Celsius degrees. The material of the substrate 15 is not limited as long as it can be used to deposit the MoS₂ semiconductor layer 11. The material of the substrate 15 can be quartz, glass, silicon dioxide, silicon, or a combination thereof. In one embodiment, the pressure P is 0.2 Pa, the temperature of the substrate 15 is 23 Celsius degrees, and the substrate 15 is a silicon substrate having a silicon dioxide layer on its surface.

In step S12, the radio-frequency power P_{RF} of the magnetron sputtering device is in a range of 150 W to 500 W. The distance T/S is 100 micrometers. The time t_{d} can be adjusted according to need. In one embodiment, the P_{RF} is 400 W.

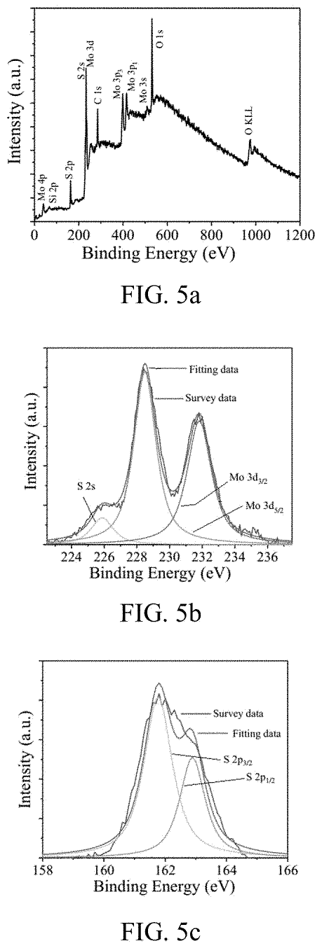

Referring to FIG. 5a shows XPS spectrum of the MoS₂ semiconductor layer 11 with all chemical elements, the amorphous MoS2 sheet has a high purity in the MoS₂ semiconductor layer 11; FIG. 5b shows XPS spectrum of the Mo 3d, the XPS spectrum of the Mo 3d comprises survey data, fitting data, Mo 3d_{5/2} data, and Mo 3d_{3/2} data, the binding energy of Mo 3d_{5/2} is 228.5 eV, the binding energy of Mo 3d_{3/2} is 231.8 eV; FIG. 5c shows XPS spectrum of the S 2p, the XPS spectrum of the S 2p comprises survey data, fitting data, S 2p_{3/2} data, and S 2p_{1/2} data, the binding energy of S 2p_{3/2} is 161.8 eV, and the binding energy of S 2p_{1/2} is 162.9 eV. According to the XPS spectrum, it can be seen that the amorphous MoS2 sheet obtained by magnetron sputtering is not oxidized.

The materials of the first electrode 13 and the second electrode 14 are conductive materials. The materials of the first electrode 13 and the second electrode 14 can be metal, indium tin oxide, conductive glue, conductive polymer, or conductive carbon nanotubes. The metals can be hafnium, titanium, gold, palladium, chromium, platinum or any combination of alloys. In one embodiment, the first electrode 13 and the second electrode 14 are spaced apart, the first electrode 13 and the second electrode 14 are respectively in direct contact with the MoS₂ semiconductor layer 11, and each of the first electrode 13 and the second electrode 14 is a composite structure of Au and Ti.

The electrical signal detector 12 can be a photocurrent detection device or a voltage detection device. When the electrical signal detector 12 is the photocurrent detection device, the photocurrent detection device comprises a power supply and an ammeter. The power supply is configured to provide a bias voltage for the MoS₂ semiconductor layer 11. The ammeter is configured to detect a change of photocurrent in the circuit loop. When the electrical signal detector 12 is the voltage detection device, the voltage detection device comprises a power supply and a voltmeter. The power supply is configured to provide a bias voltage for the MoS₂ semiconductor layer 11. The voltmeter is configured to detect a voltage change of the MoS₂ semiconductor layer 11.

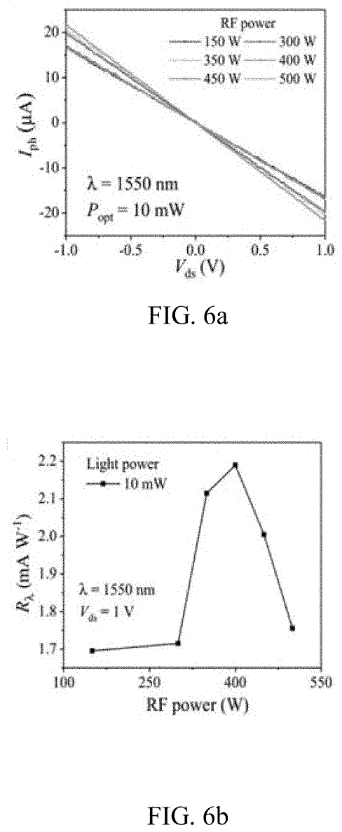

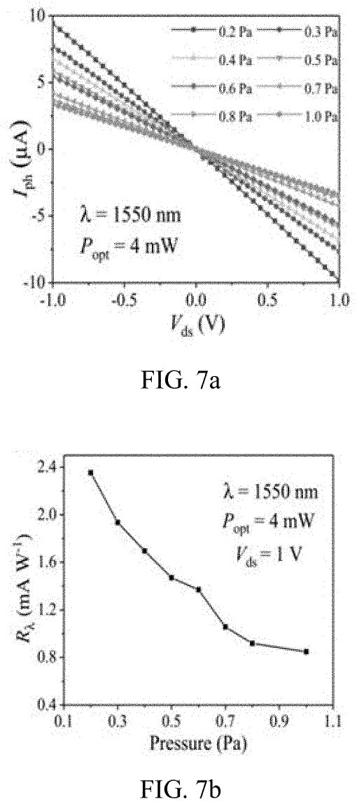

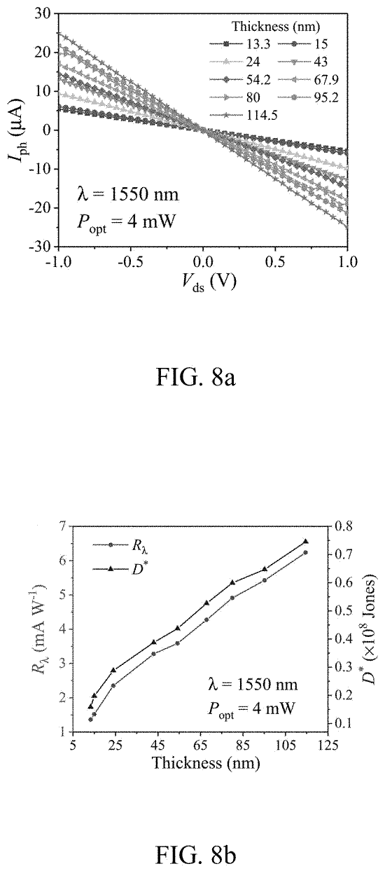

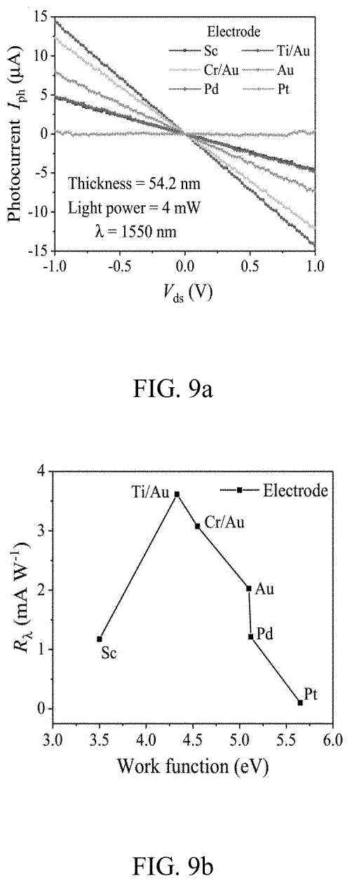

In operation, the performance parameters of the photoelectric detector 10 can be affected by factors such as the fabrication parameters of the amorphous MoS₂ sheet, the thickness of the amorphous MoS₂ sheet and electrode material. The fabrication parameters comprise the RF power and the pressure. Referring to FIG. 6a shows a graph of the photocurrent and the bias voltage at different RF power, FIG. 6b shows a graph of the relationship between the responsivity of the photoelectric detector 10 and the RF power. When an incident light irradiates the photoelectric detector 10, the wavelength and the power of the incident light are constant, and the bias voltage is also a constant, the responsivity R_{λ} of the photoelectric detector 10 changes as the RF power changes. Compared with the responsivity R_{λ} of the RF power being 300 W, the responsivity R_{λ} of the RF power being 350 W-450 W is increased by 23%-30%. When the RF power is 350-400 W, the responsivity R_{λ} is significantly improved. When the RF power is 400 W, the responsivity R_{λ} reaches a maximum. In one embodiment, the wavelength of the incident light is 1550 nm, the power Pₒₚₜ of the incident light is 10 mV, and the bias voltage is 1V. Referring to FIG. 7a shows a graph of the photocurrent and the bias voltage at different pressure; FIG. 7b shows a graph of the relationship between the responsivity of the photoelectric detector 10 and the pressure. When the wavelength and the power of the incident light are constant, and the bias voltage is also a constant, the responsivity R_{λ} of the photoelectric detector 10 decreases as the pressure increases. When the pressure is 0.2 Pa, the responsivity R_{λ} reaches a maximum. In one embodiment, the wavelength of the incident light is 1550 nm, the power Pₒₚₜ of the incident light is 4 mV, and the bias voltage is 1V. Referring to FIG. 8a shows a graph of the photocurrent and the bias voltage at different thickness of the amorphous MoS₂ sheet; FIG. 8b shows a graph of the relationship between the responsivity R_{λ}, the detection rate D* of the photoelectric detector 10 and the thickness of the amorphous MoS₂ sheet. When the wavelength and the power of the incident light are constants, and the bias voltage is also a constant, the responsivity R_{λ} and the detection rate D*of the photoelectric detector 10 increases as the thickness of the amorphous MoS₂ sheet increases. As the thickness of the amorphous MoS₂ sheet increases, the incident light can be full absorbed, the number of photons converted into electron-hole pairs increases, thereby increasing the photocurrent to obtain a great responsivity R_{λ}. In one embodiment, the wavelength of the incident light is 1550 nm, the power Pₒₚₜ of the incident light is 4 mV, and the bias voltage is 1V. Referring to FIGS. 9a and 9b, when the first electrode 13 and the second electrode 14 are made of different metals, the photoelectric detector 10 has different responsivities. FIG. 9a shows a graph of the photocurrent and the bias voltage with different electrode materials; FIG. 9b shows a graph of the relationship between the responsivity of the photoelectric detector 10 and the electrode materials. When the wavelength and the power of the incident light are constants, and the bias voltage V_{ds} and the thickness of the amorphous MoS₂ sheet are also constants, the responsivity R_{λ} of the photoelectric detector 10 is different when the electrode material is different. When the electrode material is a composite structure of Au and Ti, the responsivity R_{λ} of the photoelectric detector 10 has the maximum value, and it shows that the electrode is in good contact with the amorphous MoS₂ sheet.

The amorphous MoS₂ sheet of the photoelectric detector 10 is used as optoelectronic semiconductor, since the band gap of the amorphous MoS₂ sheet is only 0.196 eV, the amorphous MoS₂ sheet has a wide spectral range with a wavelength of 345 nanometers to 6340 nanometers, the photoelectric detector 10 has a wide spectral range with a wavelength of 345 nanometers to 6340 nanometers.

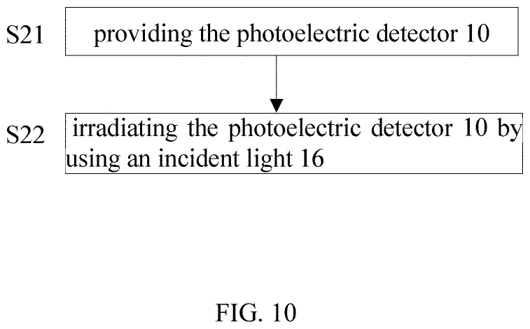

Referring to FIG. 10, a method for photoelectric conversion of one embodiment includes the following steps:

step (S21), providing the photoelectric detector 10;

step (S22), irradiating the photoelectric detector 10 by an incident light 16.

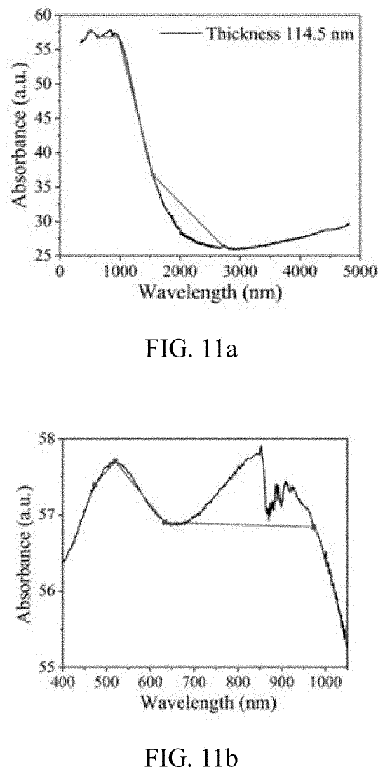

In step (S21), the photoelectric detector 10 has a wide spectral range with a wavelength from 345 nanometers to 6340 nanometers. In one embodiment, the incident light 16 is introduced to irradiate the photoelectric detector 10. The wavelength of the incident light 16 is in a range of 345 nanometers to 4814 nanometers. Referring to FIG. 11a shows a graph of the absorbance of the photoelectric detector 10 at different light wavelengths; FIG. 11b is a partial enlarged view of FIG. 11a. In one embodiment, the thickness of the amorphous MoS₂ sheet is 114.5 nanometers. The photoelectric detector 10 has a high absorption rate of incident light in the wavelength range of 345 nanometers to 4814 nanometers.

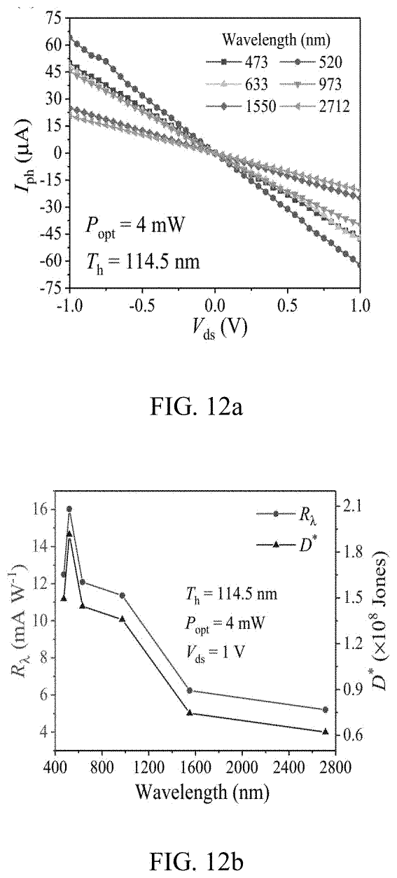

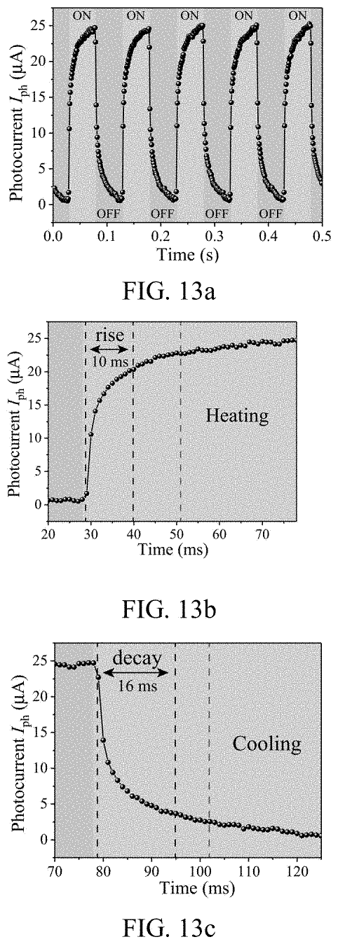

In step (S22), when the incident light 16 with different wavelengths is used to irradiate the MoS₂ semiconductor layer 11 of the photoelectric detector 10, the responsivity and the detection rate of the photoelectric detector 10 are also different. Referring to FIG. 12a shows a graph of the photocurrent and the bias voltage at different wavelengths of the incident light; FIG. 12b shows a graph of the relationship between the responsivity R_{λ}, the detection rate D* of the photoelectric detector 10 and the wavelengths of the incident light. When all the power of the incident light, the bias voltage, and the thickness of the amorphous MoS₂ sheet are constant, the photoelectric detector 10 has a high responsivity R_{λ} and a high detection rate D*. When the power Pₒₚₜ of the incident light is 4 mV, the bias voltage is 1V, and the thickness of the amorphous MoS₂ sheet is 114.5 nm, the photoelectric detector 10 has the highest responsivity and the highest detection rate for the incident light with a wavelength of 520 nm. The photoelectric detector 10 has a same change tendency in the incident light absorption rate and responsivity. Referring to FIG. 13a shows a time dependence of photocurrent measured under the illumination with a wavelength of 973 nm and at a bias voltage V_{ds}=1V; FIG. 13b shows a part of rise time of the FIG. 13a; FIG. 13c shows a part of decay time of the FIG. 13a.

Depending on the embodiment, certain of the steps of methods described may be removed, others may be added, and the sequence of steps may be altered. The description and the claims drawn to a method may comprise some indication in reference to certain steps. However, the indication used is only to be viewed for identification purposes and not as a suggestion for ordering the steps.

What is claimed is:

1. A photoelectric detector, the photoelectric detector comprising:
a substrate;
a MoS₂ semiconductor layer, located on the substrate;
a first electrode and a second electrode, spaced apart from each other and electrically connected to the MoS₂ semiconductor layer respectively; and
an electrical signal detector, configured to detect changes of photocurrent or voltage of the MoS₂ semiconductor layer;
wherein the MoS₂ semiconductor layer comprises an amorphous MoS₂ sheet.

2. The photoelectric detector of claim 1, wherein a bandgap of the amorphous MoS₂ sheet is at least 0.196 eV.

3. The photoelectric detector of claim 1, wherein the amorphous MoS₂ sheet has a spectral range with a wavelength of 345 nanometers to 6340 nanometers.

4. The photoelectric detector of claim 1, wherein a thickness of the MoS₂ semiconductor layer is in a range of 10 nanometers to 150 nanometers.

5. The photoelectric detector of claim 1, wherein the amorphous MoS₂ sheet is fabricated by magnetron sputtering in a magnetron sputtering device; a radio-frequency power of the magnetron sputtering device is in a range of 350 W to 450 W.

6. The photoelectric detector of claim 1, wherein the MoS₂ semiconductor layer, the first electrode, the electrical signal detector and the second electrode are sequentially connected in said order to form a circuit loop.

7. The photoelectric detector of claim 6, wherein the electrical signal detector comprises a power supply and an ammeter; the power supply is configured to provide a bias voltage for the MoS₂ semiconductor layer, and the ammeter is configured to detect a change of photocurrent in the circuit loop.

8. The photoelectric detector of claim 6, wherein the electrical signal detector comprises a power supply and a voltmeter; the power supply is configured to provide a bias voltage for the MoS₂ semiconductor layer, and the voltmeter is configured to detect a voltage change of the MoS₂ semiconductor layer.

9. The photoelectric detector of claim 1, wherein each of the first electrode and the second electrode is a composite structure of Au and Ti.

10. A method for photoelectric conversion, the method comprising:
providing a photoelectric detector; and
irradiating the photoelectric detector by an incident light;
wherein the photoelectric detector comprises:
a substrate;
a MoS₂ semiconductor layer, located on the substrate;
a first electrode and a second electrode, spaced apart from each other and electrically connected to the MoS₂ semiconductor layer respectively; and
an electrical signal detector, configured to detect changes of electrical properties of the MoS₂ semiconductor layer;
wherein the MoS₂ semiconductor layer comprises an amorphous MoS₂ sheet.

11. The method of claim 10, wherein the MoS₂ semiconductor layer is fabricated by magnetron sputtering, the method of magnetron sputtering comprising:
providing the substrate in a magnetron sputtering device;
depositing the MoS₂ semiconductor layer on the substrate by adjusting a radio-frequency power, a distance between a target and the substrate, and a time for deposition.

12. The method of claim 11, wherein the radio-frequency power of the magnetron sputtering device is in a range of 350 W to 450 W

13. The method of claim 10, wherein a wavelength of the incident light is in a range of 345 nanometers to 4814 nanometers.

14. The method of claim 10, wherein a thickness of the MoS₂ semiconductor layer is in a range of 10 nanometers to 150 nanometers.

15. The method of claim 10, wherein the electrical signal detector comprises a power supply and an ammeter; the power supply is configured to provide a bias voltage for the MoS₂ semiconductor layer, and the ammeter is configured to detect a change of photocurrent in the circuit loop.

16. The method of claim 10, wherein the electrical signal detector comprises a power supply and a voltmeter; the power supply is configured to provide a bias voltage for the MoS₂ semiconductor layer, and the voltmeter is configured to detect a voltage change of the MoS₂ semiconductor layer.
